(19) United States
(12) Patent Application Publication
(10) Pub. No.: US 2003/0084390 A1
(43) Pub. Date: May 1, 2003

(54) At-speed test using on-chip controller

(75) Inventors: Nagesh Tamarapalli, Wilsonville, OR (US); Janusz Rajski, West Linn, OR (US)

Correspondence Address: KLARQUIST SPARKMAN, LLP, One World Trade Center, Suite 1600, 121 S.W. Salmon Street, Portland, OR, 97204, US

(73) Assignee: Mentor Graphics Corporation

(21) Appl. No.: 10/115,337

(22) Filed: Apr. 1, 2002

Related U.S. Application Data
(60) Provisional application No. 60/345,975, filed on Oct. 26, 2001.

(51) Int. Cl. G06F 11/00; G01R 31/28

(52) U.S. Cl. 714/744

(57) ABSTRACT

A circuit is disclosed for testing integrated circuits at functional speed. In one aspect, an on-chip controller is used that accepts event data. The event data identifies a clock sequence to be used to test core logic of an integrated circuit. Multiple source clocks are generated by a phase-lock loop. The clock signals may be at the same frequency, but skewed from each other, or at different frequencies. In any event, the multiple source clocks are supplied to the on-chip controller that uses the source clocks to generate multiple test clocks. The test clocks are used to test the core logic of the integrated circuit at functional speed. In another aspect, external test equipment may supply the source clocks. Additionally, a select signal may choose whether the source clocks are supplied externally to the circuit under test or by the phase lock loop.

### CROSS REFERENCE TO RELATED APPLICATION

This application claims priority to a U.S. Provisional Patent application No. 60/345,975 entitled “At-Speed Test Using On-Chip EDT Controller” filed Oct. 26, 2001, which is hereby incorporated by reference.

### BACKGROUND

As integrated circuits are produced with greater and greater levels of circuit density, efficient testing schemes that guarantee very high fault coverage while minimizing test costs and chip area overhead have become essential. However, as the complexity of circuits continues to increase, high fault coverage of several types of fault models becomes more difficult to achieve with traditional testing paradigms. This difficulty arises for several reasons. First, larger integrated circuits have a very high and still increasing logic-to-pin ratio that creates a test data transfer bottleneck at the chip pins. Second, larger circuits require a prohibitively large volume of test data that must be then stored in external testing equipment. Third, applying the test data to a large circuit requires an increasingly long test application time. And fourth, present external testing equipment is unable to test such larger circuits at their speed of operation.

Integrated circuits are presently tested using a number of structured design for testability (DFT) techniques. These techniques rest on the general concept of making all or some state variables (memory elements like flip-flops and latches) directly controllable and observable. If this can be arranged, a circuit can be treated, as far as testing is concerned, as a combinational network. The most-often used DFT methodology is based on scan chains. It assumes that during testing, all (or almost all) memory elements are connected into one or more shift registers, as shown in the U.S. Pat. No. 4,503,537. A circuit that has been designed for test has two modes of operation: a normal mode, and a test or scan mode. In the normal mode, the memory elements perform their regular functions. In the scan mode, the memory elements become scan cells that are connected to form a number of shift registers called scan chains. These scan chains are used to shift a set of test patterns into the circuit and to shift out circuit, or test, responses to the test patterns. The test responses are then compared to fault-free responses to determine if the circuit-under-test (CUT) works properly.

Today's deep sub-micron technology, with its ever reducing feature sizes, reducing voltage levels, and increasing speed is resulting in the ICs failing with new failure mechanisms. This is due to the fact that the increasing integration levels and speed of operation of the ICs are resulting in new kind of defects. In addition, these factors also make the ICs more susceptible to defects that may previously have been benign. Thus, in order to maintain and/or improve the quality levels, it is becoming increasingly necessary to subject ICs to a variety of tests that test for different types of faults, such as the conventional stuck-at faults and delay faults.

In the conventional scan-based stuck-at fault testing, test patterns are applied to the IC at a much slower speed than the IC's functional speed. The application of a typical scan based stuck-at test pattern involves several steps. Foremost, the IC is placed in the scan or shift mode and the test pattern is shifted in from an external automated test equipment (ATE). The IC is then placed in the capture mode and the response is captured. Finally, the IC is placed back in the shift mode and the response is shifted out. In order to reduce test application time, the scanning out of the IC's response for a test pattern is usually merged with the scanning in of the subsequent test pattern. This sequence of events is usually coordinated by an external ATE, which typically supplies all the clocks in the shift as well as the capture mode.

In delay fault testing, a circuit is tested to ensure that it operates at its rated functional speed. There have been some techniques published in the literature that proposed achieving delay fault test by applying the conventional scan test patterns at functional speed. However, some of these techniques place unnecessary constraints both on the scan chain design and the ATE. For example, in some prior art solutions, the scan chains have to be designed to be operable at functional clock frequency. Additionally, the ATE has to supply clocks of the same frequency as the functional clocks. These requirements are difficult to satisfy today and will be even harder to satisfy as circuit complexity and speed increases in the future.

Thus, it is desirable to have improved methods and circuits for delay fault testing wherein an integrated circuit is tested at functional speed.

### SUMMARY

The present invention provides an improved testing circuit that tests integrated circuits at functional speed for delay-fault type testing.

In one aspect, an on-chip controller is used that accepts event data. The event data identifies a clock sequence to be used to test core logic of an integrated circuit. Multiple source clocks are generated by a phase-lock loop or an external ATE. The clock signals may be at the same frequency, but skewed from each other, or at different frequencies. In any event, the multiple source clocks are supplied to the on-chip controller that uses the source clocks along with the event data to generate multiple test clocks. The test clocks are used to test the core logic of the integrated circuit at functional speed.

In another aspect, the on-chip controller may include an event data register and an event generator. The event data register stores event data, which may be supplied by the ATE. The event generator receives the event data from the register and generates multiple test clocks that are fed to the core logic during a capture mode of operation.

The clock supplied by the ATE to supply event data does not need to be related to the clocks operating at functional speed. Furthermore, if the ATE does not stop the clock used to supply event data during a capture mode of operation, a clock synchronizer may be used to synchronize the switching of the clocks from a shift mode of operation to a capture mode of operation. Such a synchronizer is not necessary if the ATE stops the clock used to supply the event data during a capture mode of operation. Thus, in order to achieve at-speed test of the core logic it is not necessary to perform at-speed shift of the scan chains. At-speed clocks may be supplied only during the capture mode. This observation simplifies the constraints on the design of the scan chains as they do not have to be designed to be operable at functional clock frequency. In addition, the on-chip PLL may be used to supply the clocks in the capture mode to reduce constraints on the ATE.

In yet another aspect, at-speed test does not necessitate at-speed shifting of scan chains. In order to remove unnecessary constraints on the scan chain design, the speed at which scan chains are shifted may be de-coupled from the speed at which the logic is tested. Additionally, the frequency of the shift and capture clocks need not necessarily be related to one another. For the current designs, typically shift clock is about 20 MHz or so, whereas the functional clocks may be upto 1 GHz and there may or may not be any relation between their frequencies.

When switching between the shift and capture modes, an at-speed transition is not needed. The controller may be such that speed of transition of mode from shift to functional and vice-versa has no affect on the actual test itself. This simplifies the shifting in of the test data and shifting out of the circuit response. The transition of clocks from shift to functional mode clocks and vice-versa is desirably accomplished in a glitch-free and meta-stability-free manner.

In yet another aspect, the controller should be flexible enough to allow a wide variety of events in the capture mode. The controller may also be programmable and lend itself to the creation of wide variety of sequence of events in the capture mode.

These and other aspects and features of the invention are described below with reference to the accompanying drawings.

### BRIEF DESCRIPTION OF THE DRAWINGS

FIG. 1 is a system block diagram of a circuit for testing an integrated circuit at operational or functional speed.

FIG. 2 is a detailed circuit diagram of a controller used in the circuit of FIG. 1.

FIG. 3 is a detailed circuit diagram of an event data register used in the circuit of FIG. 2.

FIG. 4 is a detailed circuit diagram of an event generator used in the circuit of FIG. 2.

FIG. 5 is a detailed circuit diagram of an output block used in the circuit of FIG.2.

FIG. 6 is a flow chart of a method for performing at-speed test of an integrated circuit.

FIG. 7 is a timing diagram for generating multiple testing clocks using the circuit of FIG. 2, with the source clocks being at the same frequency, but skewed from each other.

FIG. 8 is another exemplary circuit diagram of an event generator.

FIG. 9 is another exemplary timing diagram showing source clocks of differing but related frequencies.

FIG. 10 is a circuit diagram of an output block used in conjunction with the event generator of FIG. 8.

FIG. 11 is a block diagram of a clock synchronizer that may be used in the circuit of FIG. 1.

FIG. 12 is a block diagram of a circuit for testing an integrated circuit at operational or functional speed and for selectably switching source clocks between an external ATE and internal phase-lock loop.

### DETAIL DESCRIPTION

System Overview

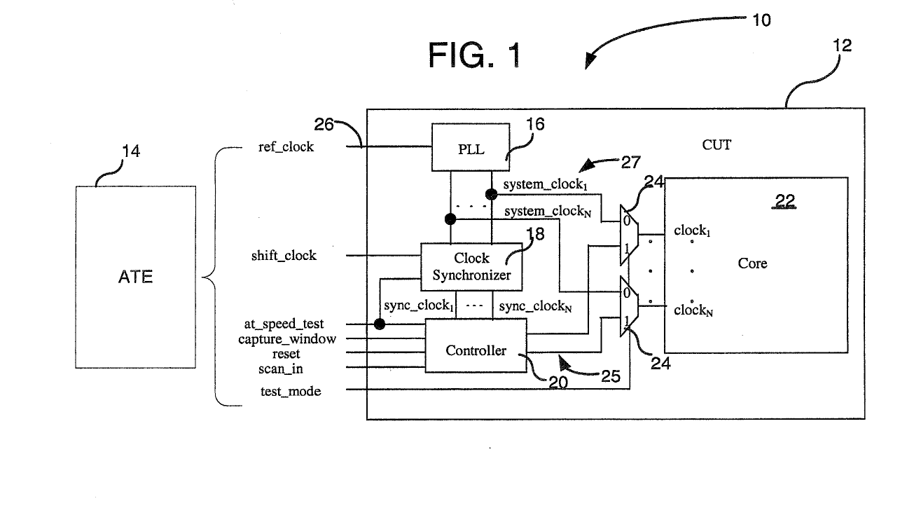

FIG. 1 shows a system 10 for testing a circuit under test (CUT) 12 at operational speed. An ATE 14 supplies test signals to a phase lock loop (PLL) 16, a clock synchronizer 18, and a controller 20. An integrated circuit core 22 includes logic to be tested and also includes scan chains (not shown) into which test patterns are shifted. The core receives multiple clock signals clock₁ through clock_{N}. Multiplexers 24 are coupled to the multiple clocks and switch between test clock signals 25 supplied from the controller 20 and system clocks 27 supplied from the PLL. The select line of the multiplexers 24 is controlled by a pin called test_mode. When the test_mode is at logic value zero, i.e., functional mode, the core clocks are driven by the PLL clocks. However, when the test_mode is at logic value one, i.e., test mode, the core clocks are driven by the controller 20. Those skilled in the art, however, will recognize that the test_mode pin could be active high or low depending on the design.

The PLL 16 receives a reference clock 26 as input and provides system clocks 27, system_clock₁ through system_clock_{N}, that are used to clock the core in functional or operating mode. In general, the frequency of the reference clock 26 is much smaller than that of the system clocks supplied by the PLL, which enables the core logic to function at a much higher frequency while reducing the constraints on the entity supplying the reference clock.

The clock synchronizer 18 is used to ensure transitions between clocks to the controller 20 occur in a glitch-free and meta-stability resistant manner. Specifically, during a shift mode of operation where test patterns are loaded into scan chains in the core 22, the ATE supplies the clock to the core. During a capture mode where at-speed testing occurs, the PLL 16 supplies clocks to the core. When switching back and forth between shift and capture mode, the clock synchronizer synchronizes the clocks between the ATE and the PLL to ensure that clock signals to the controller 20 are stable and glitch free. The inputs to the clock synchronizer 18 include the PLL system clocks and the shift_clock from the ATE. In addition, the at_speed_test input is used to switch between these clocks. When at_speed_test signal is at logic value of one, the system clock is passed on to the corresponding sync_clock output of the clock synchronizer 18. However, when at_speed_test is at logic value zero, shift clock is passed on to all the sync_clock outputs. The clock synchronizer circuit is a well-known and well-researched problem. Many different clock synchronization techniques may be used as is well understood in the art.

Turning briefly to FIG. 11, a sample clock synchronization circuit is shown. This figure presents a clock selector circuit 30 for switching between one of four input clocks (clk a, clk b, clk c, clk d). The circuit is shown with four blocks for purposes of illustration: the stable selects block 32, the stable decoder block 34, the synchronous selects block 36, and the output block 38. Select signals 40 are input to the stable selects block 32 to select which one of the multiple clocks a, b, c, and d are to be used as a system clock 42. Generally, the stable selects block 32 ensures the select signals 40 are stable before being used to switch the system clock 42. The stable decoder block 34 is used to decode selection signals from the stable selects block 32 and decides whether to use such selection signals or whether to maintain its current state because the selection signals are not stable. The synchronous selects block 36 synchronizes decoded selection signals from the decoder block 34 with the input clocks a, b, c, d. Finally, the output block 38 receives the clock signals themselves, decoded signals from the stable decoder block 32, and synchronous signals from the synchronous selects block 36 and outputs the system clock 42.

Returning to FIG. 1, the controller 20 takes as input the sync_clock outputs of the clock synchronizer 18. In addition, the controller 20 has the following inputs—at_speed_test, capture_window, reset, and scan_in. The outputs of the controller 20 are used to drive the core clocks during the scan test. At_speed_test and capture_window are used to put the controller 20 in a capture mode as further described below. The scan_in is used in conjunction with the shift clock to scan in event data as further described below. The reset signal resets the controller. Some or all of these signals may be used since the number of signals used is design dependent. For example, the reset may easily be removed. Additionally, the at_speed_test and capture_window may be combined into one signal in certain situations.

The Controller

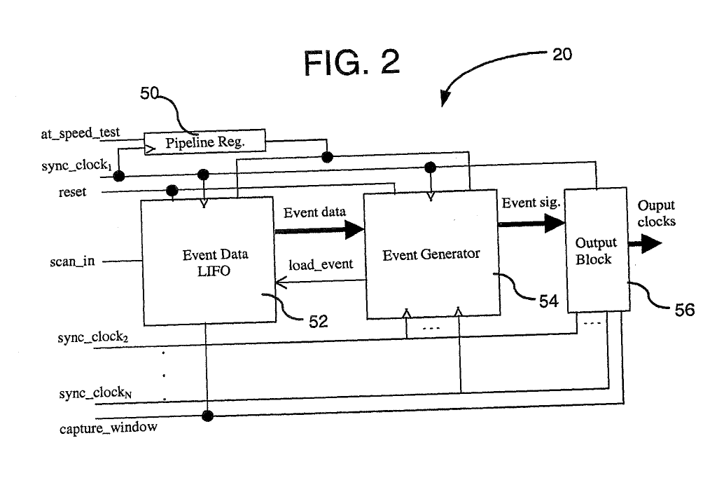

FIG. 2 shows the controller 20 in more detail. The following components are shown: a pipeline register 50, an event data register 52 (e.g., a LIFO), an event generator 54, and an output block 56. The pipeline register 50 delays the at_speed_test signal by at least as many clock cycles as the latency of the clock synchronizer. This delayed version of at_speed_test signal is supplied to the event data register 52 and event generator 54. The clock synchronizer 18 (FIG. 1), on the other hand, receives the non-delayed version of at_speed_test signal to switch between shift and capture mode. The switching of clocks has an inherent latency, the number of cycles of which depends on the actual implementation of the clock synchronizer. Because of this latency, a delayed or pipelined version of at_speed_test is used to drive the event data register 52 and event generator 54 to ensure that the capture window events are not prematurely generated. The event data register 52 stores event data representing the desired sequence of capture window events. The number of stages in this register depends on the maximum possible number of events in the capture window as well as the format used for representing the events.

A sample event data format for a design has the following fields:

1) Last Event—1 bit that when set indicates that the event is the last event in the capture window.

2) Clock Enables—N bits corresponding to N system clocks. When any bit is set, the corresponding clock is enabled for that event.

3) Event Offset—M bits (e.g., 3) that represent a number of cycles that a next event is delayed from the previous event.

The event generator 54 interprets the event data supplied by the event data register 52 and generates one or more event signals in response thereto. The output block 56 combines the event signals with the sync_clocks to generate the test clocks for testing the core.

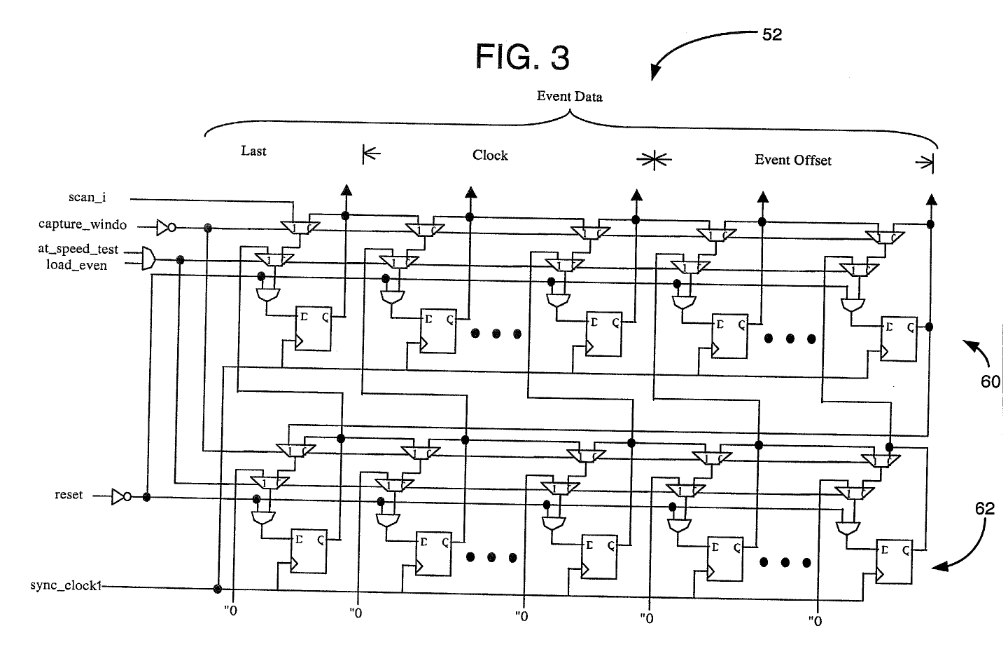

FIG. 3 shows a more detailed example of the event data register 52. In this example, the event data register is a LIFO, but other registers may be used. The event data register 52 has the following inputs: sync₁₃ clock1, reset, capture_window, scan_in, the pipelined at_speed_test, and load_event. The output of the event data register is data corresponding to the current event. The LIFO has two sets of memory elements 60, 62. The top set of memory elements 60 outputs the event data to the event generator 54. The bottom set of memory elements 62 are used to load the next event in parallel to the top set of elements 60. Both sets of memory elements 60, 62 are also serially coupled together so that during shift mode all of the memory elements may be serially loaded through data on the scan_in line. The optional reset input when asserted resets the event data register. A logic value “1” on the capture_window input indicates that the capture window of the current test pattern is in progress. Conversely a logic value “0” on the capture_window indicates that the shift window of the current pattern is in progress. Even though one may think that scan enable can be used for this purpose, it may not always work due to the fact that certain patterns may leave scan enable in the shift mode even during the capture window. Thus, a separate capture_window input is used to be certain that signal is always set to appropriate value indicating the shift/capture window. If the scan enable can be guaranteed to exhibit the required behavior then capture_window input can indeed be driven by the scan enable signal.

During the shift window, event data is shifted into the event data register 52 by placing the data on scan_in input and pulsing sync_clock1 (which during the shift window is the slow ATE supplied shift clock). After the completion of the shift, the ATE 14 starts the capture window by changing the capture_window from “0” to “1”. Shortly thereafter, the at_speed_test is asserted by the ATE to enable the controller 20 to fire a sequence of events as determined by the event data scanned into the register 52. The register 52 holds its value from the time capture_window is set to “1” to the time at_speed_test is asserted. Thus, there can be an arbitrary amount of time from the beginning of the capture window to the occurrence of the at-speed clock pulses. Also, as previously noted, in order to prevent the firing of events before the clocks are safely switched by the clock synchronizer, a pipelined version of the at_speed_test is used to drive the event data register 52. Once the at_speed_test is asserted with capture_window being “1”, the event data register places a new event data on its output in each clock cycle the load_event handshaking signal is asserted by the event generator.

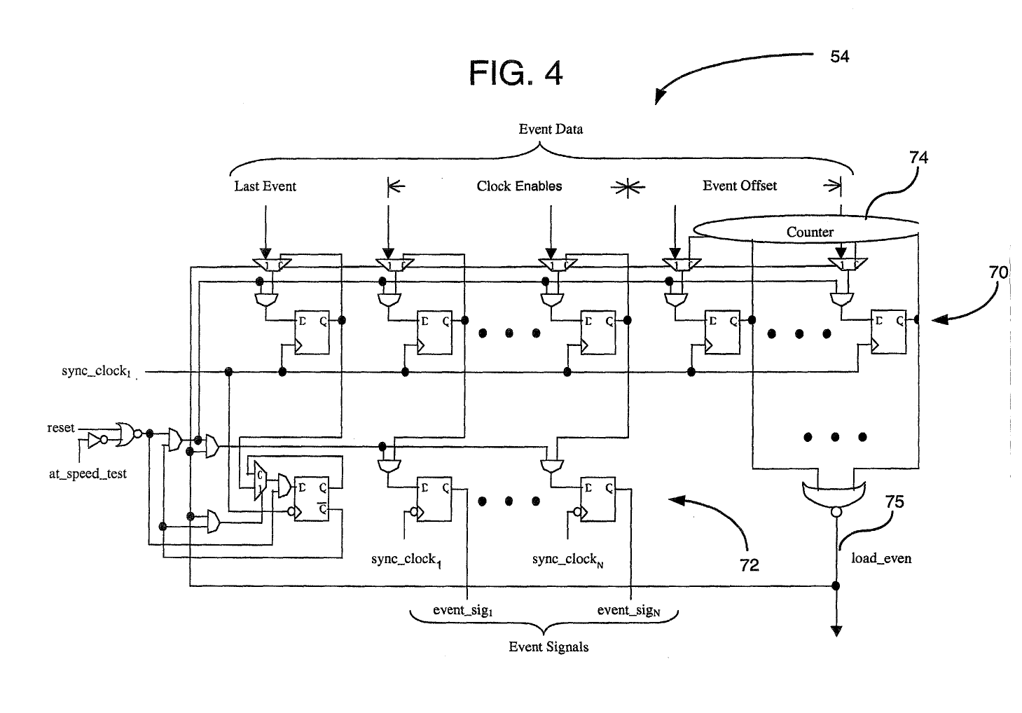

FIG. 4 shows the event generator 54 in more detail. The event generator 54 receives the event data supplied by the event data register 52, interprets the event data, and supplies event signals at the appropriate time. The inputs of the event generator 54 are sync_clock₁ through sync_clock_{N}, reset, pipelined at_speed_test, and event data. The outputs of the event generator 54 are the event signals and load_event, which is a handshake signal supplied to event data register 52 indicating the readiness of generator 54 to accept new event data. The event generator 54 has first and second sets of memory elements 70, 72. Memory elements 70 are used to receive the event data from the event data register 52. Memory elements 72 are used to output the event signals. A counter 74 receives the event offset and counts down a number of cycles. Once the counter 74 reaches zero, a load_event flag 75 is set signaling the event data register 52 that the next event is ready to be loaded.

The operation of the event generator 54 is as follows. First, an optional reset may be asserted causing all the memory elements 70, 72 in the event generator 54 to be reset. The memory elements are also reset as long as the at_speed_test signal is held at “0” or all the events in the capture window have been generated. Thus, the event signals, which are utilized by the output block 56 to generate the test clocks driving the core, are at reset state before the beginning of the at-speed test and after the occurrence of the last event in the capture window. Once the at_speed test input is asserted, the event generator 54 generates precisely the events dictated by the data stored in the event data register and holds its event signals outputs at reset state at all other times. Using the counter 74, the event generator counts the number of clock pulses specified by the event offset field and passes on the clock enable field of the event data to its event signal outputs. Every time new event data is placed on the event signals output, the event generator indicates its readiness to accept next event data by asserting the load_event signal. Once the last event has been generated, as indicated by the first bit of event data, the event signals are held at reset state.

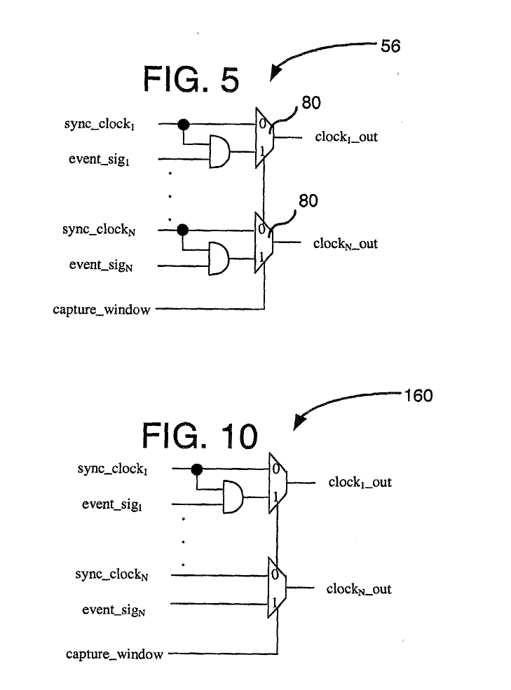

FIG. 5 shows the output block 56 of the controller 20. The output block 56 contains clock multiplexers 80. The select line of the multiplexers 80 is driven by the capture_window input. The other inputs of the output block 56 include event signals supplied by the event generator 54 and the sync_clock₁ through sync_clock_{N}, supplied by the clock synchronizer 18. During the shift window, i.e., when capture_window is at “0”, the sync_clocks are passed through the multiplexers 80 without any modification. However, during the capture window, i.e., when capture_window is at “1”, the test clocks are a gated combination of the sync_clocks and the corresponding event signals.

System Operation

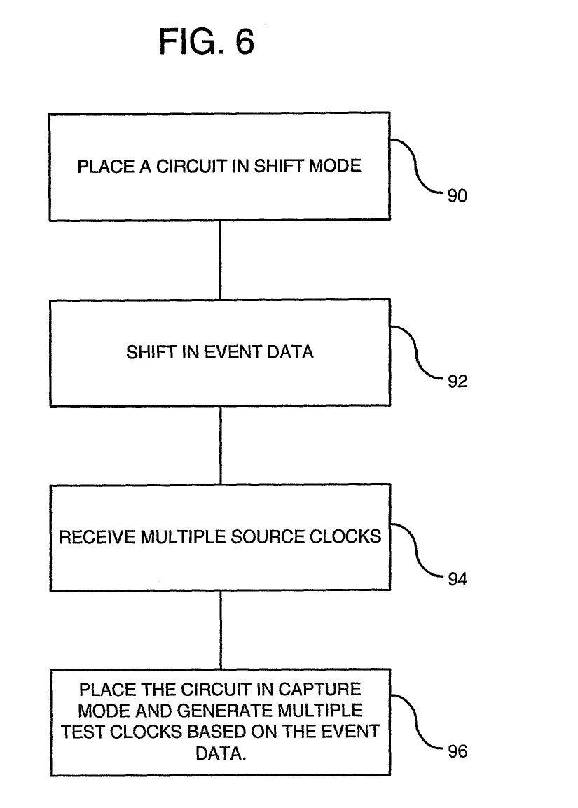

FIG. 6 shows a flowchart of a method for at-speed testing. In process block 90, the ATE 14 places the IC in a shift mode of operation. During the shift mode, event data is shifted into the event data register 52 (process block 92). One technique for accomplishing this is to supply event data from the ATE 14 on the scan_in line and clock data using the shift_clock. Other techniques for shifting in the event data may also be used. In process block 94, multiple source clocks are received. For example, the multiple source clocks may be generated from PLL 16. The clocks may be the same frequency, but skewed from one another or at a different frequency. The clocks may also be sourced from the ATE 14. In process block 96, the circuit is placed in a capture mode and multiple test clocks are generated based on the event data. The test clocks are associated with the multiple source clocks.

Example with Source Clocks with Same Frequencies

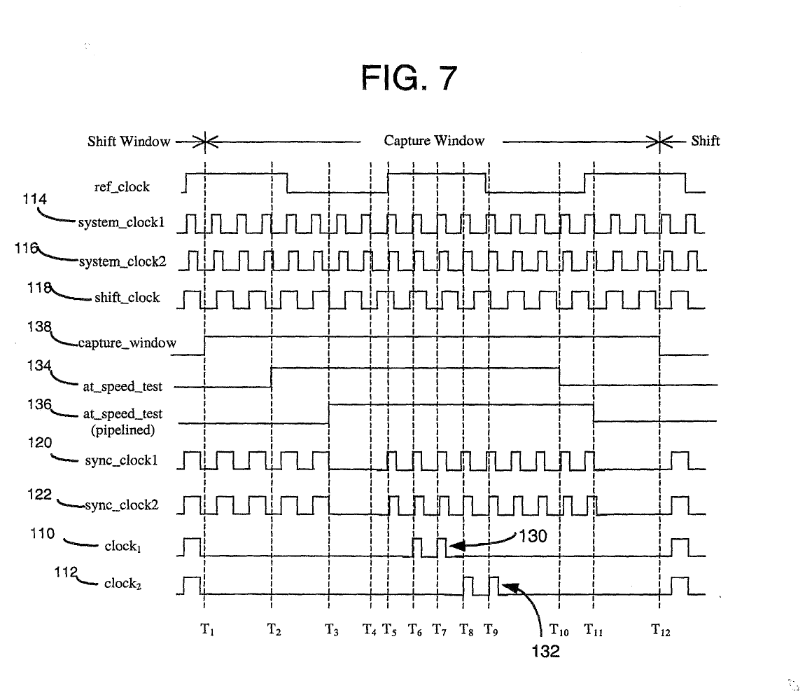

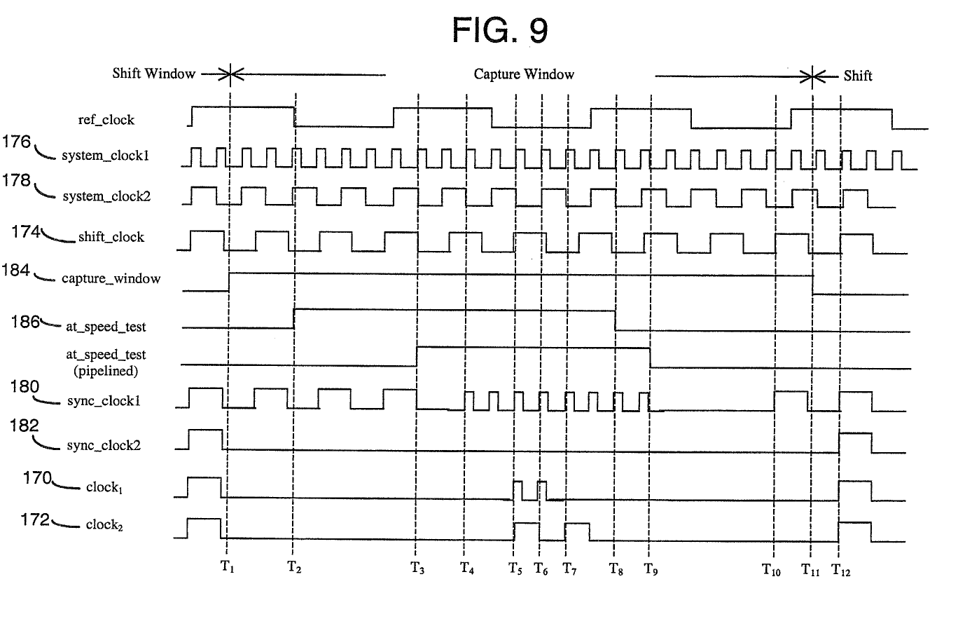

FIG. 7 shows a timing diagram showing the interaction of various blocks of the overall circuit. For the sake of simplicity, a circuit with two test clocks 110, 112 is considered for the timing diagram. However, the circuit may easily be expanded to handle additional clocks. Additionally, it should be recognized that the timing diagram of FIG. 7 has source clocks 114, 116 (e.g., system_clock1 and system_clock2) that are at the same frequency, but slightly skewed from one another. A later example (discussed in FIG. 9) shows system clocks at a different frequency. As shown in FIG. 7, the ATE supplies a slow shift clock 118 while the on-chip PLL generates the fast system clocks 114, 116. The frequency of the shift and system clocks may not have any integral relation. The outputs of clock synchronizer are depicted at 120, 122, as sync_clock1 and sync_clock2. The test clocks 110, 112 generated by the controller 20 and supplied to the core 22 are labeled clock₁ and clock₂.

The capture_window signal 138 is changed by the ATE from “0” to “1” at time T₁, indicating the transition from shift to capture window. The at_speed_test signal 134 is also changed by the ATE from “0” to “1” at time T₂, enabling the on-chip controller 20 to start firing the sequence of events based on the scanned event data. The ATE changes these signals based on a test cycle utilizing the slow shift clock. Also there can be an arbitrary amount of time between T₁ and T₂. As long as the capture_window and at_speed_test signals are kept at “1” and “0” respectively, the controller holds its state and maintains the clocks at their off-states.

The change in the at_speed_test signal at time T₂ triggers the clock synchronizer to switch the selected clock from shift clock 118 to the system clocks 114, 116. This clock switching does not take place instantaneously due to the inherent latency in the clock switching process. The amount of latency varies based on the implementation of the clock synchronizer. In the example timing diagram, the latency of the clock synchronizer is assumed to be two clock cycles of the current selected clock (which is shift_clock 118) followed by two cycles of the new clock to be selected (which is the system clocks 114, 116). After the transition of the at_speed_test signal at T₂, two clock cycles of shift_clock occur by T₃. From then on, two clock cycles of system_clock take place by T₄, thus completing the clock switching process by T₄ (due to the slight skew between system_clock1 and system_clock2, the clock switching for sync_clock2 is completed slightly after T₄.)

The example timing diagram assumes an at_speed_test pipeline register containing two stages, causing the change in at_speed_test signal at T₂ to require two shift_clock pulses to reach the output of the pipeline register at time T₃. As previously stated, the on-chip controller 20 uses the pipelined at_speed_test signal instead of the primary input at_speed_test signal to ensure that the controller does not fire the events (generate the test clocks) prematurely based on the sync_clock pulses between T₂ and T₃. Between T₂ and T₄, the clock synchronizer is in the process of switching the clocks from the shift_clock 118 to system_clocks 114, 116. Thus pulses on sync_clock 120, 122 between T₂ and T₄ should not affect the controller 20, which is ensured by driving the on-chip controller with a pipelined at_speed_test signal 136 instead of the primary input at_speed_test signal 134.

Following the successful switch of clocks by the clock synchronizer at time T₄, at time T₆, the first of a sequence of events takes place on clock₁ 110 and clock₂ 112. The controller 20 ignores the pulses on sync_clock1 and sync_clock2 at T₅ due to the one cycle offset of the event at T₆. The test clocks are then generated as shown at 130 and 132. The burst of events that has begun at T₆ continues through T₉, generating a total of four events with zero offset between them. The last event in the example capture window takes place at T₉. An event offset of one between the event at T₇ and T₈, for example, would delay the clock pulses 132 so that they start at T₉ instead of T₈.

After waiting for a predetermined number of shift clock cycles, sufficient enough to allow the on-chip controller 20 to finish generation of the events, the ATE pulls at_speed_test signal 134 low at time T₁₀. This change of value of at_speed_test signal causes the clock synchronizer 18 to switch sync_clock1 120 and sync_clock2 122 from system clocks 114, 116 to the shift_clock 118. It also causes the pipelined at_speed_test signal 136 to change at T₁₁. Finally, at time T₁₂, the ATE changes the capture_window signal 138 from “1” to “0”, indicating the beginning of a new shift window. Note that the event at_speed_test going low at T₁₀ and the event capture_window going low at T₁₂ should be separated by at least the latency of the clock synchronizer to ensure proper scan in of the data. Also note that from the time the last event has occurred at T₉ to the time pipelined capture_window signal has gone low at T₁₂, the clocks clock₁ and clock₂ have remained unchanged despite the pulses on sync_clock1 120 and sync_clock2 122. Thus the on-chip controller generates precisely the set of events determined by the event data that is scanned into the event data LIFO and keeps the clocks at their off-state all other times.

In summary, the ATE 14 indicates the beginning of the capture window by changing the capture_window signal from “0” to “1”. The ATE then asserts the at_speed_test signal 134 after an arbitrary amount of time, indicating to the on-chip controller 20 to generate the sequence of the events in the capture window. The on-chip controller fires the sequence of events determined by the scanned in event data and maintains the clocks at their off-states at all other times. The ATE 14, after waiting for a pre-determined number of shift clock cycles, de-asserts the at_speed_test signal 134. ATE 14 then changes the capture_window signal 138 from “1” to “0” after allowing enough time for the clock synchronizer 18 to complete the clock switch.

Example Controller with Source Clocks of Differing but Related Frequencies

The controller 20 can also generate test clocks using multiple source clocks of differing, but related frequencies. Only blocks that have modifications from the above-described implementation are described.

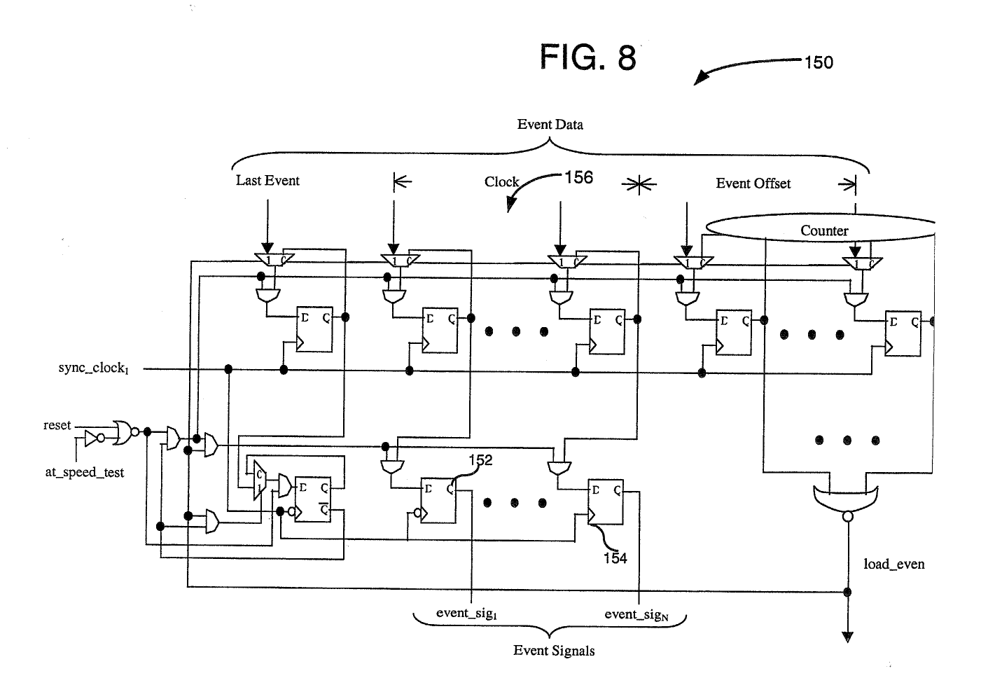

FIG. 8 illustrates an event generator 150 of a controller 20 employed for testing a design with N clocks, clock₁ through clock_{N}. For purposes of illustration, clock₁ is assumed to be one of the fastest clocks. Thus, the frequency of all the slower clocks is an integral multiple of the frequency of clock₁. FIG. 8 presents a different clocking scheme from that of FIG. 4. In particular, all the memory elements (e.g. flip flops), such as 152, 154, which are driving the event signal outputs, are driven by clock₁ in FIG. 8, unlike in FIG. 4 where the memory elements 72 are driven by their corresponding sync_clocks. The memory elements, such as 152, that correspond to the clocks of fastest frequency are all triggered by the falling edge of sync_clock₁, whereas memory elements, such as 154, corresponding to the slower are triggered by the rising edge of clock₁.

The event data format for this embodiment is similar to that described above. However, the “clock enables” field 156 is interpreted differently for the slower clocks. For these slower clocks, a “1” indicates that the corresponding clock value is one for that cycle (of the fastest clock), whereas a “0” indicates that the corresponding clock value is zero for that cycle (of the fastest clock). For clocks of the fastest frequency, a “1” and a “0” are interpreted as before. That is a “1” indicates that the corresponding fastest clock is enabled for that event, whereas a “0” indicates that the corresponding fastest clock is disabled for that event. Thus, the events in the capture window are all cyclized based on the cycles of the fastest clock. For the fastest clocks, the “clock enables” field 156 indicates whether the corresponding clock is enabled or disabled, whereas for slower clocks the “clock enables” field indicates the value of the corresponding clock. Note that the interpretation used for the enables of the slow clocks can be utilized to generate scan enable signals for various clock domains including the fastest clock domains.

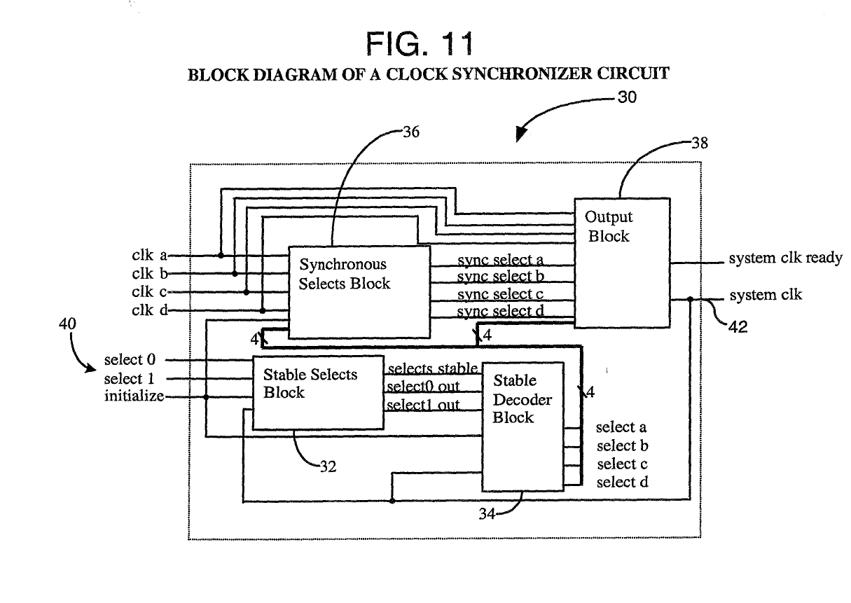

An output block 160 for the controller 20 of this embodiment is illustrated in FIG. 10. During the capture window, i.e., when capture_window signal is “1”, the output clock_{1—}out corresponding to one of the fastest clock clock₁, is obtained by ANDing the sync_clock₁ with event_sig₁, as before. For clock_{N—}out, the output corresponding to one of the slower clock clock_{N}, the event signal event₁₃ sig_{N} is used directly in the capture window.

FIG. 9 shows an example timing diagram using the event generator 150 of FIG. 8 and the output block 160 of FIG. 10. Although only two test clocks are shown (clock₁ 170 and clock₂ 172), additional clocks can easily be handled by the circuit. The frequency of clock₂ is assumed to be half that of the frequency of clock₁ for purposes of this example. Other differences in frequencies may also be used. A shift clock 174 may or may not have any relation to the frequencies of clock₁ and clock₂. The unmodified system clocks are shown as system_clock₁ 176 and system_clock₂ 178, whereas the outputs of clock synchronizer are depicted as sync_clock1 180 and sync_clock2 182.

The capture_window signal 184 is changed by the ATE from “0” to “1” at time T₁, indicating the transition from shift to capture window. The at_speed_test signal 186 is also changed by the ATE from “0” to “1” at time T₂. This change in the at_speed_test signal reaches the output of the pipeline register at time T₃ and also causes the clock synchronizer 18 to select the system clock 176, 178 by time T₄.

Following the switching of clocks by the synchronizer 18, the next event occurs at time T₅, where the first of a sequence of events take place on clock₁ 170 and clock₂ 172. The burst of test clocks that began at T₅ continues through to T₇. Inbetween these times, two pulses occur on each clock₁ and clock₂ 170, 172. During the capture cycle, pulses of the slower clock, clock₂, are derived from the event_sig₂ output of the event generator 150. As before, after waiting for a predetermined number of cycles of the shift clock, the ATE 14 pulls at_speed_test signal 186 low at time T₈. This change in at_speed_test propagates to the output of the pipeline register by time T₉ and also causes the clock synchronizer to switch back to shift clock by time T₁₀. Finally, at time T₁₁ the ATE 14 changes the capture_window signal 184 from “1” to “0” indicating the beginning of a new shift window. Note that the event at_speed_test going low at T₈ and the event capture_window going low at T₁₁ should be separated by at least the latency of the clock synchronizer to ensure proper scan in of the data. Also, the on-chip controller 20 ignores any pulses on the synchronous clocks from the time the last event has occurred at time T₇ to the time the capture_window is changed at time T₁₁. Thus, the on-chip controller generates precisely the set of events determined by the event data and keeps the clocks at their off-states at all other times.

Example Circuit with Selectable System Clocks

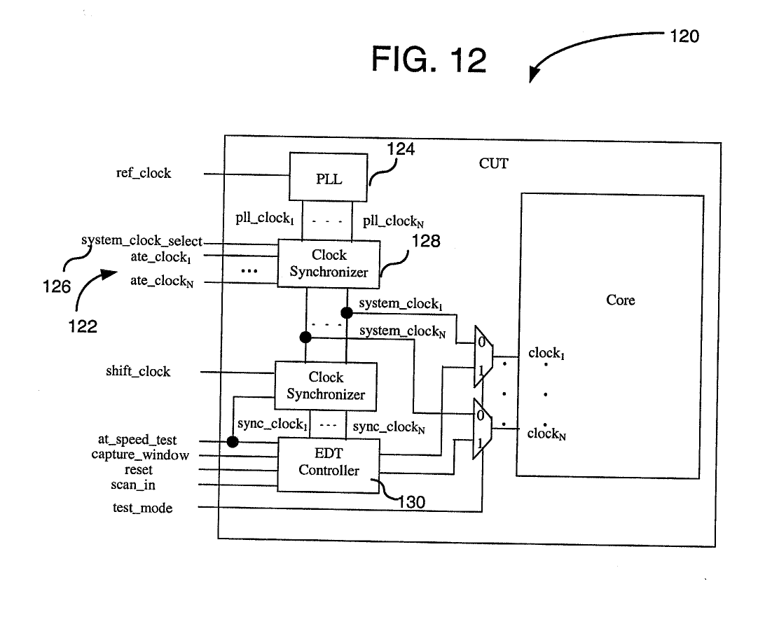

FIG. 12 illustrates a circuit-under-test 120 with selectable system clocks. The system clocks can be supplied by either the automatic test equipment (ATE), as indicated at 122 or the on-chip PLL 124. This selection is achieved by changing the system_clock_select signal 126 (supplied by the ATE) from one logic state indicating the selection of ATE clocks to the other logic state indicating the selection of the PLL clocks. Since there may or may not be any relation between the frequencies of the ATE clocks and the PLL clocks, it is desirable to employ a clock synchronizer 128 to properly switch the system clocks between the ATE clocks and the PLL clocks. Subsequent to the proper selection of the system clocks the on-chip controller 130 operates in the same manner as outlined previously.

Conclusion

Thus, one possible protocol for scan based delay fault test includes placing the IC in shift mode and shifting in the test pattern with slow ATE supplied clocks, placing the IC in capture mode and capturing its response using on-chip PLL supplied clocks, and finally placing the IC back in shift mode and shifting out the response using slow ATE supplied clocks.

For a scan based delay fault test utilizing the above protocol to be successful, it is desirable that the protocol is simple and reliable. For example, the effectiveness of the delay fault test should not depend on the speed of transition of system mode from shift to capture and vice-versa. Also, it is desirable that there are no assumptions made about the frequencies of the shift and the capture clocks. Since the shift clocks may be supplied by the ATE and the capture clocks may be supplied by the on-chip PLL, these features have the beneficial effect of de-coupling these two clock sources. In addition, the above-described protocol can handle both a programmable and a non-programmable on-chip PLL. If the on-chip PLL is programmable, then the automatic test pattern generation (ATPG) tool generating the delay fault test patterns should restrict the sequence of events in the capture window to the set of events compatible with the PLL. However, if the on-chip PLL is not programmable then in order to facilitate testing of various timing relations there should be a programmable on-chip controller capable of producing the sequence of events in the capture window deemed necessary by the ATPG tool. Notice that even if the on-chip PLL is programmable there may be a need for on-chip controller, though simpler, for co-ordinating various events.

Having illustrated and described the principles of the illustrated embodiments, it will be apparent to those skilled in the art that the embodiments can be modified in arrangement and detail without departing from such principles. For example, although certain signals are described as active high or active low, those skilled in the art will recognize that such active states can easily be changed. Additionally, although a particular hardware was described for the controller, such hardware can easily be modified. Those skilled in the art will recognize that there are numerous hardware designs that can be used to accept multiple source clocks and all such designs cannot be described. Still further, although the event data is generally described as being shifted, the event data is more generally “supplied” to the on-chip controller, which could be serially or in parallel.

In view of the many possible embodiments, it will be recognized that the illustrated embodiments include only examples of the invention and should not be taken as a limitation on the scope of the invention. Rather, the invention is defined by the following claims. We therefore claim as the invention all such embodiments that come within the scope of these claims.

We claim:

1. A method for testing an integrated circuit at operational speed, comprising:
supplying event data into an on-chip controller;
providing multiple source clocks;
using the controller, receiving the multiple source clocks and generating at least two different test clocks, each test clock having a sequence of one or more clock pulses based on the event data; and
testing the integrated circuit at operational speed using the test clocks.

2. The method of claim 1, wherein each test clock is associated with a different source clock.

3. The method of claim 1, wherein the multiple source clocks are at the same frequency, but skewed from one another.

4. The method of claim 1, wherein the multiple source clocks are at different frequencies from each other.

5. The method of claim 1, wherein the event data format includes an event offset, the event offset corresponding to a delay of a number of clock cycles between a previous event and a next event.

6. The method of claim 1, wherein the event data format includes a clock-enables field that controls which test clocks are generated.

7. The method of claim 6, wherein the clock-enables field has multiple bits, each bit corresponding to a test clock.

8. The method of claim 1, wherein providing multiple clocks includes providing a phase-lock loop that receives a reference clock and that generates the multiple clocks in response thereto.

9. The method of claim 1, wherein the event data is provided by an external ATE.

10. The method of claim 1, wherein providing multiple clocks includes providing a phase lock loop that generates the multiple clocks and synchronizing the multiple clocks with a clock used to supply the event data.

11. The method of claim 10, wherein the clock used to supply the event data is supplied from an external ATE.

12. The method of claim 1, wherein supplying event data includes supplying the event data into an event data register.

13. The method of claim 12, further including supplying the event data stored in the event data register into an event generator that generates the test clocks.

14. The method of claim 1, wherein the controller generates at least three different test clocks, each test clock being associated with a different source clock.

15. The method of claim 1, wherein the controller generates at least four different test clocks, each test clock being associated with a different source clock.

16. An apparatus for testing an integrated circuit at operational speed, comprising:
an on-chip controller couplable to core logic in the integrated circuit, the on-chip controller including:
an event data register that receives and stores event data; and
an event generator coupled to the event data register, the event generator couplable to two or more source clocks and that generates two or more test clocks, wherein the integrated circuit is tested at operational speed.

17. The apparatus of claim 16, wherein the event data register is a LIFO coupled to an external ATE that supplies the event data.

18. The apparatus of claim 16, wherein the event generator includes event offset logic that creates a programmable delay between pulses.

19. The apparatus of claim 16, further including a phase-lock loop that generates multiple clock signals that are skewed from one another or that are at differing frequencies, the multiple clock signals being provided to the event generator.

20. The apparatus of claim 19, further including a clock synchronizer coupled between the phase lock loop and the controller.

21. The apparatus of claim 20, wherein the clock synchronizer is further coupled to an external ATE and wherein the clock synchronizer synchronizes switching between an ATE supplied clock and the multiple clock signals supplied from the phase lock loop.

22. The apparatus of claim 16, further including a pipeline register coupled to the event data register and the clock synchronizer.

23. The apparatus of claim 16, wherein the event data register includes a clock enables field that controls the generation of events for between 1 to N clock signals wherein N is any integer greater than 2.

24. The apparatus of claim 16, wherein the event data register includes a last event field that indicates the last event to occur during the capture mode of operation.

25. The apparatus of claim 16, wherein the two or more source clocks are at the same frequency but are skewed from one another.

26. The apparatus of claim 16, wherein the two or more source clocks are at different frequencies from each other.

27. An apparatus for testing an integrated circuit at operational speed, comprising:
means for supplying event data into an on-chip controller;
means for generating multiple source clocks;
means for receiving the generated source clocks and generating at least two test clocks based on the event data; and
means for testing the integrated circuit using the test clocks.

28. The apparatus of claim 27, wherein the means for supplying includes external ATE means.

29. The apparatus of claim 27, wherein the means for generating the source clocks includes phase lock loop means.

30. The apparatus of claim 27, wherein the means for generating the test clocks includes a controller means having event data register means and event generating means.

31. The apparatus of claim 27, wherein the source clocks are either at the same frequency but skewed from one another, or at a different frequency but synchronous.
